(19) United States
(12) Patent Application Publication
(10) Pub. No.: US 2026/0173762 A1
(43) Pub. Date: Jun. 18, 2026

(54) Ultrasonic Element, Information Device, And Super-Directional Speaker

(71) Applicant: SEIKO EPSON CORPORATION, Tokyo (JP)

(72) Inventors: Chikara KOJIMA, Matsumoto (JP); Motoki TAKABE, Shiojiri (JP); Masao NAKAYAMA, Matsumoto (JP)

(21) Appl. No.: 19/419,676

(22) Filed: Dec. 15, 2025

(30) Foreign Application Priority Data
Dec. 16, 2024 (JP) 2024-219660

(51) Int. Cl. H10N 30/50; B06B 1/06; H04R 1/32; H04R 17/10; H10N 30/00; H10N 30/87

(52) U.S. Cl. CPC H10N 30/503; B06B 1/0681; H04R 1/323; H04R 17/10; H10N 30/706; H10N 30/872

(57) ABSTRACT

An ultrasonic element includes: a substrate having a vibration region and a non-vibration region surrounding the vibration region; a first electrode disposed inside the vibration region; a piezoelectric body disposed on the substrate to cover the first electrode; and a second electrode provided on the piezoelectric body, in which a direction in which the substrate, the first electrode, the piezoelectric body, and the second electrode are stacked is a stacking direction, and a thickness of the substrate along the stacking direction is 2.0 μm or more and 10.0 μm or less.

The present application is based on, and claims priority from JP Application Serial Number 2024-219660, filed Dec. 16, 2024, the disclosure of which is hereby incorporated by reference herein in its entirety.

### BACKGROUND

### 1. Technical Field

The present disclosure relates to an ultrasonic element, an information device including the ultrasonic element, and a super-directional speaker including the ultrasonic element.

### 2. Related Art

In the related art, an information device in which a transmission position of a sound wave is limited to a narrow range is known (for example, JP-A-2004-112213). JP-A-2004-112213 relates to a small electronic device including a super-directional speaker, and is a device that modulates an audio signal and a high-frequency signal into an amplitude-modulated wave signal, amplifies the amplitude-modulated wave signal into an amplified signal, converts the amplified signal into acoustic vibration, and emits the acoustic vibration. In the device disclosed in JP-A-2004-112213, by inputting the amplified signal into an ultrasonic element made of a compact ceramic piezoelectric element, a super-directional beam-shaped sound field is formed. As amplitude-modulated sound waves propagate in the air, nonlinear interactions occur, generating a distortion component, so that a low-frequency component therein is audible to a listener.

JP-A-2004-112213 is an example of the related art.

However, it is difficult to stably drive an ultrasonic wave having a frequency of 200 kHz or less in an ultrasonic element mounted on a small electronic device in the related art. That is, in the related art, in order to stably output an ultrasonic wave having a frequency of 40 kHz to 500 kHz with directionality, it is necessary to set a diameter of an opening width of the speaker to 15 mm or more, and it is difficult to mount the speaker on the small device.

### SUMMARY

An ultrasonic element according to an aspect of the present disclosure includes: a substrate having a vibration region and a non-vibration region surrounding the vibration region; a first electrode disposed inside the vibration region; a piezoelectric body disposed on the substrate to cover the first electrode; and a second electrode provided on the piezoelectric body, in which a direction in which the substrate, the first electrode, the piezoelectric body, and the second electrode are stacked is a stacking direction, and a thickness of the substrate along the stacking direction is 2.0 μm or more and 10.0 μm or less.

### BRIEF DESCRIPTION OF THE DRAWINGS

FIG. 1 is a schematic diagram illustrating a schematic configuration of a super-directional speaker according to a first embodiment.

FIG. 2 is a diagram illustrating an example of an output range of an ultrasonic wave from the super-directional speaker according to the first embodiment.

FIG. 3 is a plan view illustrating a schematic configuration of an ultrasonic element according to the first embodiment.

FIG. 4 is a diagram illustrating a relationship between a resonance frequency of the ultrasonic element and a thickness of a substrate in the first embodiment.

FIG. 5 is a diagram illustrating an example of a relationship between the thickness of the substrate and a width of a vibration region when a resonance frequency of the ultrasonic element is 40 kHz in the first embodiment.

FIG. 6 is a diagram illustrating an example of a relationship between the thickness of the substrate and the width of the vibration region when the resonance frequency of the ultrasonic element is 75 kHz in the first embodiment.

FIG. 7 is a diagram illustrating an example of a relationship between the thickness of the substrate and the width of the vibration region when the resonance frequency of the ultrasonic element is 100 kHz in the first embodiment.

FIG. 8 is a diagram illustrating an example of a relationship between the thickness of the substrate and the width of the vibration region when the resonance frequency of the ultrasonic element is 500 kHz in the first embodiment.

FIG. 9 is a diagram illustrating displacement of the vibration region for outputting ultrasonic waves having a predetermined frequency in the ultrasonic element according to the first embodiment and an ultrasonic element according to a comparative example.

FIG. 10 is a diagram illustrating a schematic configuration of the ultrasonic element in the comparative example in FIG. 9.

FIG. 11 is a schematic diagram illustrating a schematic configuration of an ultrasonic element according to a second embodiment.

FIG. 12 is a schematic diagram illustrating a schematic configuration of an information device according to a third embodiment.

FIG. 13 is a schematic diagram illustrating an example of a wireless speaker including the super-directional speaker according to the present disclosure.

FIG. 14 is a schematic diagram illustrating an example of a car navigation device including the super-directional speaker according to the present disclosure.

FIG. 15 is a schematic diagram illustrating an example of an indoor content output device including the super-directional speaker according to the present disclosure.

FIG. 16 is a schematic diagram illustrating an example of an operation panel including the information device according to the present disclosure.

### DESCRIPTION OF EMBODIMENTS

### First Embodiment

Hereinafter, the first embodiment according to the present disclosure will be described.

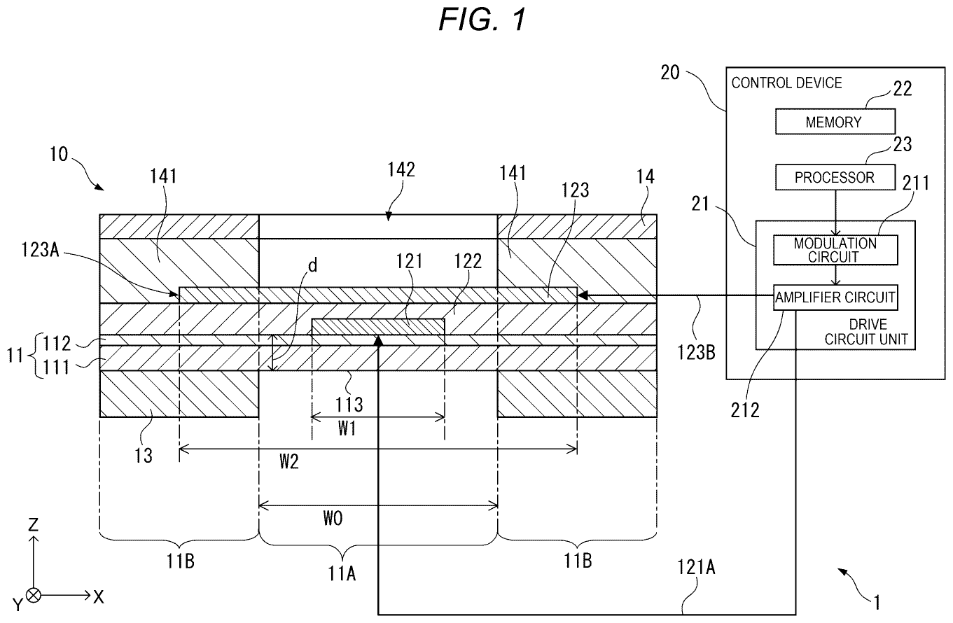

FIG. 1 is a schematic diagram illustrating a schematic configuration of a super-directional speaker 1 according to the embodiment.

As illustrated in FIG. 1, the super-directional speaker 1 includes an ultrasonic element 10 and a control device 20 that controls the ultrasonic element 10. The super-directional speaker 1 according to the embodiment is a speaker that generates audible sound only in a predetermined audible field, and can be suitably incorporated into, for example, a small device or a portable device such as a smartphone, a tablet terminal, or a notebook personal computer.

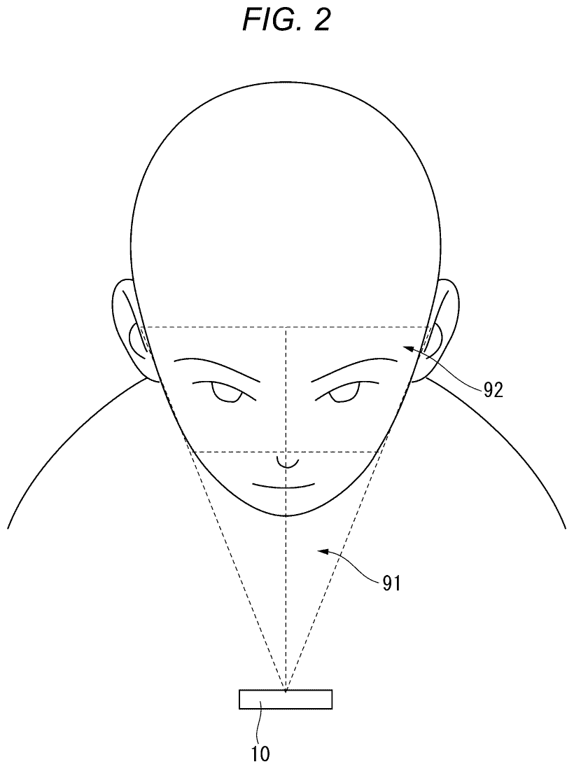

FIG. 2 is a diagram illustrating an example of an output range of an ultrasonic wave output from the super-directional speaker 1.

In the super-directional speaker 1 according to the embodiment, in the control device 20, an audio signal in an audible sound frequency band based on an audible sound and an ultrasonic signal in an ultrasonic frequency band are combined and modulated to obtain a modulated signal, and an acoustic signal obtained by amplifying the modulated signal is input to the ultrasonic element 10, thereby outputting an ultrasonic wave as acoustic vibration from the ultrasonic element 10.

Since the ultrasonic wave has high straightness, the ultrasonic wave has higher directionality than the audible sound having a low frequency. A directional angle of the ultrasonic wave output from the ultrasonic element 10 depends on a frequency of the ultrasonic wave. As the frequency of the ultrasonic wave becomes higher, spread of an ultrasonic beam becomes narrower, so that the directional angle also becomes narrower. Therefore, it is preferable to appropriately set a frequency band of the ultrasonic wave to be used according to a purpose of the super-directional speaker 1.

When sound waves are output into the air, compression and expansion of the air occur linearly. When a frequency of the audible sound is f1 and a frequency of the ultrasonic wave is f2 and amplitude modulation is performed, a sideband component (f2±f1) is generated. However, when the sound wave is an ultrasonic wave and the ultrasonic wave is output at a high sound pressure, compression and expansion of the air become nonlinear due to a high frequency and a large amplitude of the ultrasonic wave, and a waveform of the ultrasonic wave during propagation is distorted (nonlinear effect). As in the embodiment, when an amplified signal obtained by amplitude modulating and amplifying the audio signal and the ultrasonic signal is input to the ultrasonic element 10, as illustrated in FIG. 2, an ultrasonic wave is linearly propagated in a range from the ultrasonic element 10 to a predetermined distance (near field 91), and an audible field 92 is formed in front of the near field 91 (on a side away from the ultrasonic element 10). In the audible field 92, a waveform of the ultrasonic wave is distorted due to the nonlinear effect as described above. As a result, the frequency f1 of the audible sound, which is a difference between the frequency f2 of the ultrasonic wave and the sideband component (f2±f1), is generated.

In the super-directional speaker 1 as described above, it is necessary to form a beam width in an appropriate directivity range, and the higher the frequency of the ultrasonic wave, the stronger directionality of the beam width. In order to form the target audible field 92 (in order to determine a distance of the near field 91), it is necessary to appropriately increase a sound pressure of a speaker output. Further, in order to reproduce the audible sound in the audible field 92, it is necessary to appropriately select the frequency f2 of the ultrasonic wave, and a condition capable of stable driving within a range of at least 40 kHz or more and 500 kHz or less is required.

In the embodiment, the ultrasonic element 10 having a configuration capable of being stably driven within the range of 40 kHz or more and 500 kHz or less is provided. Hereinafter, a specific configuration of such the ultrasonic element 10 will be described.

### Configuration of Ultrasonic Element 10

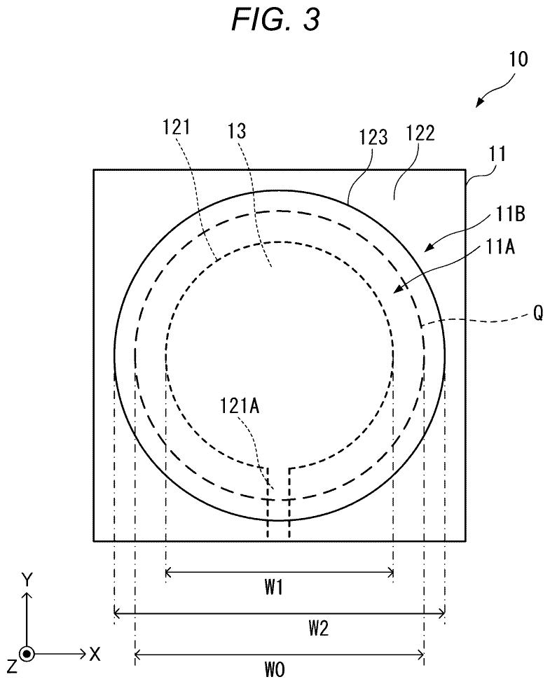

FIG. 3 is a plan view illustrating a schematic configuration of the ultrasonic element 10 according to the embodiment.

As illustrated in FIG. 1, the ultrasonic element 10 according to the embodiment includes a substrate 11, a first electrode 121, a piezoelectric body 122, a second electrode 123, a vibration suppressor 13, and a support substrate 14.

Here, in the embodiment, the first electrode 121, the piezoelectric body 122, and the second electrode 123 are stacked on/above the substrate 11. A stacking direction in which the substrate 11, the first electrode 121, the piezoelectric body 122, and the second electrode 123 are stacked is defined as a Z direction. A plane that intersects with the Z direction (orthogonal in the embodiment) is defined as an XY plane, and two orthogonal axial directions in the XY plane are defined as an X direction and a Y direction, respectively.

The substrate 11 includes a base portion 111 and a surface layer portion 112. The base portion 111 is a flat plate-shaped substrate implemented with a semiconductor substrate, and is made of Si as the semiconductor substrate in the embodiment. The surface layer portion 112 is a portion resulting from a surface treatment of a surface of the base portion 111. In the embodiment, for example, one surface side of the base portion 111 made of Si is oxidized to form a SiO₂ layer, and then a Zro₂ layer is stacked thereon by sputtering or the like. That is, in the embodiment, the surface layer portion 112 includes the SiO₂ layer and the Zro₂ layer.

In the embodiment, a dimension (thickness) of the substrate 11 along the Z direction is 2.00 μm or more and 10.00 μm or less, and more preferably 2.08 μm or more and 6.77 μm or less. A thickness dimension of the surface layer portion 112 is sufficiently smaller than that of the base portion 111, and the thickness of the substrate 11 is dominated by the base portion 111.

Assuming that a −Z-side surface of the substrate 11 (surface at which surface layer portion 112 is not provided) is called a first surface 113, the first surface 113 is formed so that arithmetic surface roughness is within a range of 0.4 μm±0.5 μm. That is, in the embodiment, the first surface 113 of the substrate 11 is formed by polishing. Accordingly, the arithmetic surface roughness of the first surface 113 of the substrate 11 can thus be smaller than that achieved when the first surface 113 is formed, for example, by etching.

The substrate 11 has a vibration region 11A and a non-vibration region 11B, which surrounds the vibration region 11A, as illustrated in FIGS. 1 and 3. The vibration region 11A is a region that vibrates by applying a voltage to the piezoelectric body 122 via the first electrode 121 and the second electrode 123, and ultrasonic waves are output from the ultrasonic element 10 by the vibration of the vibration region 11A. In FIG. 3, a boundary between the vibration region 11A and the non-vibration region 11B is indicated by a broken line Q.

Meanwhile, the non-vibration region 11B is a region in which vibration is restricted. In the embodiment, providing the vibration suppressor 13 at the first surface 113 of the non-vibration region 11B of the substrate 11 suppresses vibration of the non-vibration region 11B.

The vibration suppressor 13 is made of a resin providing a vibration suppressing effect. The resin to be used is not limited to a specific resin, and can, for example, be a resist resin such as an epoxy resin, an acrylic resin, or a novolac resin. The vibration suppressor 13 covers the entire non-vibration region 11B and is not provided in the vibration region 11A.

In the embodiment, an example in which the vibration suppressor 13 is provided at the first surface 113 of the substrate 11 is illustrated, but a support leg portion 141 bonding the substrate 11 and the support substrate 14 may function as the vibration suppressor.

The first electrode 121 is provided in the vibration region 11A of the substrate 11 on the surface layer portion 112 of the substrate 11 when viewed from the Z direction. That is, a width W1 of the first electrode 121 is smaller than a width W0 of the vibration region 11A. In the embodiment, the vibration region 11A and the first electrode 121 are circular when viewed from the Z direction, and in this case, the width W1 of the first electrode 121 means a diameter of the first electrode 121, and the width W0 of the vibration region 11A means a diameter of the vibration region 11A.

The vibration region 11A is not limited to a circular shape, and may have another shape such as a rectangular shape. When the vibration region 11A has a shape having a minor axis direction and a major axis direction such as a rectangle or an ellipse, the first electrode 121 is also formed in a shape similar to that of the vibration region 11A, and a minor axis direction and a major axis direction of the first electrode 121 are matched with the minor axis direction and the major axis direction of the vibration region 11A. In this case, the first electrode 121 is disposed with respect to the vibration region 11A to satisfy a relationship of (a dimension of the first electrode 121 in the minor axis direction)< (a dimension of the vibration region 11A in the minor axis direction).

A first extraction electrode 121A is coupled to the first electrode 121, and the first extraction electrode 121A extends from the vibration region 11A to the non-vibration region 11B on the surface layer portion 112 and is electrically coupled to the control device 20 via a first terminal portion illustrated) (not provided at a predetermined position of the non-vibration region 11B of the substrate 11.

The piezoelectric body 122 is provided from the vibration region 11A to the non-vibration region 11B on the surface layer portion 112 of the substrate 11. That is, the piezoelectric body 122 covers the entire vibration region 11A and first electrode 121. The piezoelectric body 122 may be formed over an entire surface of the substrate 11. The piezoelectric body 122 is made of a perovskite transition metal oxide containing Pb, and is, for example, PZT containing Pb, Zr, and Ti in the embodiment.

The second electrode 123 is provided on the piezoelectric body 122 across a region from the vibration region 11A to the non-vibration region 11B. That is, a width W2 of the second electrode 123 is larger than the width W1 of the first electrode 121 and the width W0 of the vibration region 11A when viewed from the Z direction (W1<W0<W2).

An end edge of the second electrode 123 is located on the piezoelectric body 122, and the support leg portion 141 described later covers the piezoelectric body 122 from an end edge 123A of the second electrode 123. Accordingly, since the end edge 123A of the second electrode 123 is protected by the support leg portion 141, it is possible to reduce burning or cracking of the piezoelectric body 122 near the end edge 123A of the second electrode 123.

A second extraction electrode 123B is coupled to the second electrode 123. The second extraction electrode 123B extends from the piezoelectric body 122 to a second terminal portion (not illustrated) provided at a predetermined position of the non-vibration region 11B of the substrate 11, and is electrically coupled to the control device 20 via the second terminal portion.

When viewed from the Z direction, a portion where the first electrode 121, the piezoelectric body 122, and the second electrode 123 overlap each other in the vibration region 11A functions as a piezoelectric element 12, and when a drive voltage is applied between the first electrode 121 and the second electrode 123, the vibration region 11A is bent in the Z direction, and ultrasonic waves are output in the Z direction.

In the embodiment, as illustrated in FIG. 3, the vibration region 11A and the first electrode 121 are circular, but the second electrode 123 may not be circular. That is, a shape of the second electrode 123 is not limited as long as the second electrode 123 covers the vibration region 11A and the first electrode 121. When the vibration region 11A and the first electrode 121 have a shape having a minor axis direction and a major axis direction when viewed from the Z direction, the second electrode 123 may be disposed with respect to the vibration region 11A so as to satisfy a relationship of (a dimension of the first electrode 121 in the minor axis direction < (a dimension of the vibration region 11A in the minor axis direction)< (a dimension of the second electrode 123 in the minor axis direction).

A thickness of the support substrate 14 in the Z direction n is sufficiently larger than that of the substrate 11, and is bonded to the piezoelectric body 122 and the second electrode 123 via the support leg portion 141. In the example in FIG. 1, the piezoelectric body 122 covers the entire substrate 11, but a part of the surface layer portion 112 of the substrate 11 may be exposed. In this case, the support leg portion 141 may also be bonded to the surface layer portion 112.

As described above, since the support leg portion 141 covers a range from the end edge 123A of the second electrode 123 to the piezoelectric body 122, a boundary between the end edge 123A of the second electrode 123 and the piezoelectric body 122 is not exposed, and it is possible to reduce problems such as burning or cracking.

As illustrated in FIG. 1, the support substrate 14 may be provided with a hole portion 142 penetrating in the Z direction at a position facing the vibration region 11A. In this case, the ultrasonic wave can be output not only to the −Z side but also to a +Z side by vibration of the vibration region 11A.

A resonance frequency H of the ultrasonic element 10 can be expressed as a function of a thickness d of the substrate 11 and the width W0 of the vibration region 11A (H=f(d, W0)). The width W0 of the vibration region 11A is a minimum width of the vibration region 11A, and in the embodiment, since the vibration region 11A is circular, the width W0 is the diameter. There are a plurality of combinations of the thickness d of the substrate 11 and the width W0 of the vibration region 11A for obtaining a specific resonance frequency, but in the embodiment, a configuration for stably outputting an ultrasonic wave having a frequency of 40 kHz to 500 kHz from the ultrasonic element 10 is required.

Therefore, the discloser of the present disclosure has newly found a condition of the thickness d of the substrate 11 for stably outputting an ultrasonic wave having a frequency of 40 kHz to 500 kHz from the ultrasonic element 10.

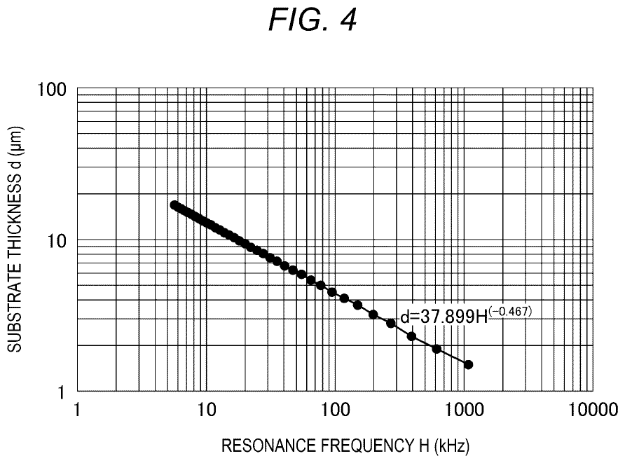

FIG. 4 is a diagram illustrating a relationship between the resonance frequency of the ultrasonic element 10 and the thickness d of the substrate 11 satisfying the above condition in the embodiment.

That is, in the embodiment, a relationship between the resonance frequency H of the ultrasonic element 10 and the thickness d of the substrate 11 is determined to satisfy a condition of the following formula (1).

$$d = 37.899 \times {H}^{- 0.467} \qquad ( 1 )$$

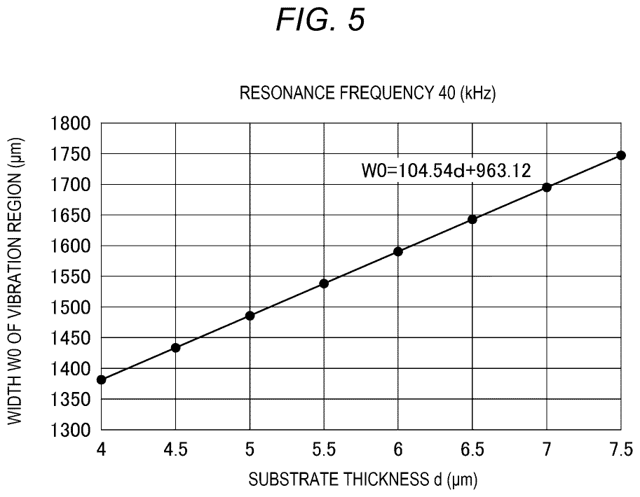

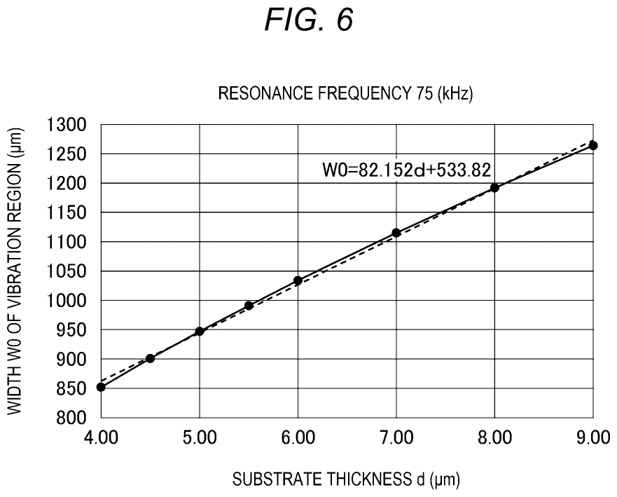

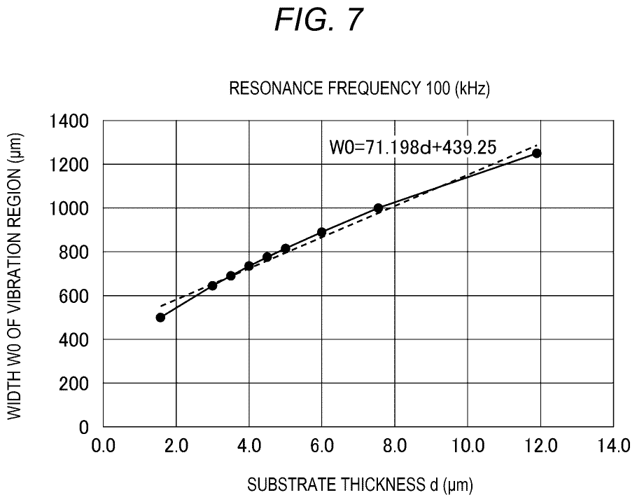

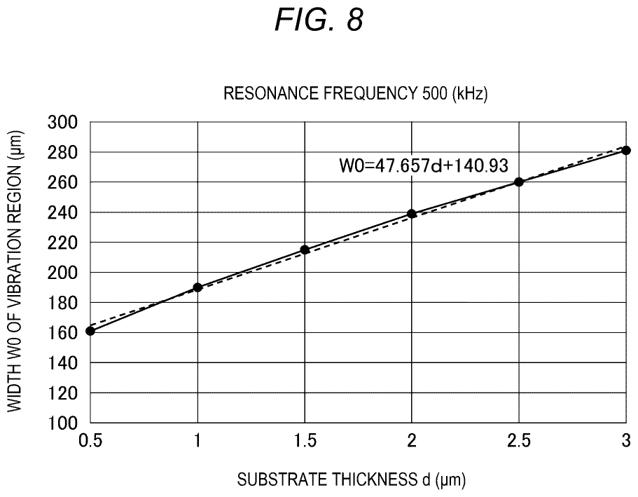

FIGS. 5 to 8 are diagrams illustrating a relationship between the thickness d of the substrate 11 in the ultrasonic element 10 and the width W0 of the vibration region 11A. FIG. 5 is a diagram when the resonance frequency H of the ultrasonic element 10 is 40 KHz. FIG. 6 is a diagram when the resonance frequency H of the ultrasonic element 10 is 75 kHz. FIG. 7 is a diagram when the resonance frequency H of the ultrasonic element 10 is 100 kHz. FIG. 8 is a diagram when the resonance frequency H of the ultrasonic element 10 is 500 kHz.

The relationship between the thickness d of the substrate 11 and the width W0 of the vibration region 11A with respect to the resonance frequency of the ultrasonic element 10 can be obtained in advance as illustrated in FIGS. 5 to 8.

Therefore, in the embodiment, the thickness d of the substrate 11 corresponding to a target resonance frequency (a center frequency of the ultrasonic wave output from the ultrasonic element 10) is determined based on the formula (1) from the resonance frequency corresponding to a frequency band of the ultrasonic wave output from the ultrasonic element 10. Thereafter, the width W0 of the vibration region 11A is obtained based on the relationship between the thickness d of the substrate 11 corresponding to the target resonance frequency and the width W0 of the vibration region 11A.

For example, when the resonance frequency of the ultrasonic wave is 75 kHz, the thickness d of the substrate 11 and the width W0 of the vibration region 11A satisfy a condition of the following formula (2).

$$W 0 = 82.152 \times d + 533.82 \qquad ( 2 )$$

Therefore, when the resonance frequency of the ultrasonic wave is 75 kHz, d=5.05 μm can be calculated from the formula (1), and W0=948.69 μm can be calculated from the formula (2).

Similarly, the thickness d of the substrate 11 and the width W0 of the vibration region 11A can be calculated for other resonance frequencies.

The thickness d of the substrate 11 corresponding to the resonance frequency 40 kHz is d=6.77 and the width W0 of the vibration region μm, 11A corresponding to FIG. 5 is W0=1670.84 μm. The thickness d of the substrate 11 corresponding to the resonance frequency 500 kHz is d=2.08 μm, and the width W0 of the vibration region 11A corresponding to FIG. 8 is W0=240.05 μm.

As described above, in the ultrasonic element 10 according to the embodiment capable of outputting the ultrasonic wave from 40 kHz to 500 kHz, the thickness d of the substrate 11 is preferably 2.08 μm ≤d≤6.77 μm, and the width W0 of the vibration region 11A corresponding thereto is 1670.84 μm≥W0 ≥240.05 μm.

The resonance frequency of the ultrasonic element 10 is a frequency of an ultrasonic wave capable of outputting an ultrasonic wave having a maximum sound pressure from the ultrasonic element 10, and the ultrasonic wave actually output from the ultrasonic element 10 can be output in a range of a predetermined bandwidth centered on the resonance frequency. Therefore, as described above, even when the thickness of the substrate 11 is 2.0 μm or more and 10.0 μm or less, it is possible to output the ultrasonic wave of 40 kHz or more and 500 kHz or less.

### Frequency Specification of Ultrasonic Element 10

Next, frequency characteristics of the ultrasonic element 10 according to the embodiment will be described.

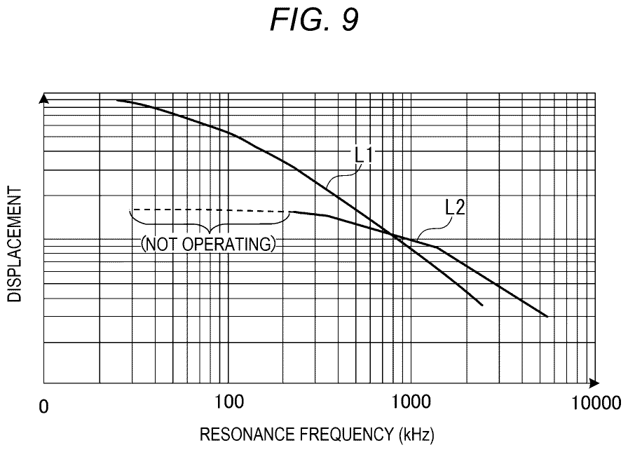

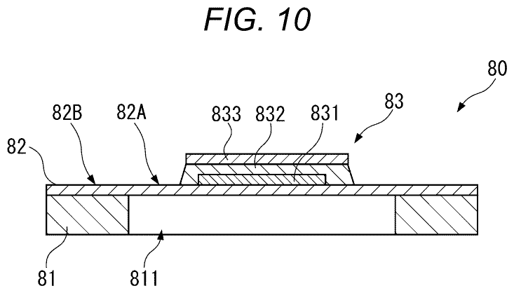

FIG. 9 is a diagram illustrating displacement of the vibration region for outputting ultrasonic waves having a predetermined frequency in the ultrasonic element 10 according to the embodiment and an ultrasonic element according to a comparative example. In FIG. 9, a line L1 indicates the characteristics of the ultrasonic element 10 in the embodiment, and a line L2 indicates characteristics of an ultrasonic element 80 according to the comparative example. FIG. 10 is a diagram illustrating a schematic configuration of the ultrasonic element 80 according to the comparative example.

As illustrated in FIG. 10, the ultrasonic element 80 according to the comparative example includes a substrate 81, a vibration plate 82, and a piezoelectric element 83 stacked on the vibration plate 82. Here, the substrate 81 is made of Si similarly to the embodiment, and includes an opening 811 penetrating the substrate 81. The vibration plate 82 is formed by stacking a SiO₂ layer and a Zro₂ layer, and is provided on the substrate 11 to close the opening 811. A portion of the vibration plate 82 that closes the opening 811 (a portion overlapping the opening 811 when viewed from the Z direction) is a vibration region 82A in the ultrasonic element 80 according to the comparative example.

The piezoelectric element 83 is formed by sequentially stacking a first electrode 831, a piezoelectric body 832, and a second electrode 833. The first electrode 831, the piezoelectric body 832, and the second electrode 833 are stacked in the vibration region 82A to form the piezoelectric element 83. Although not illustrated, similarly to the embodiment, a first coupling electrode coupled to the first electrode 831 and a second coupling electrode coupled to the second electrode 833 extend from the vibration region 82A to a non-vibration region 82B on the vibration plate 82, and are coupled to corresponding terminal portions. Accordingly, by applying a drive voltage between the first electrode 831 and the second electrode 833, the vibration region 82A is vibrated and ultrasonic waves are output.

The ultrasonic element 80 according to the comparative example as described above is formed as follows. That is, one surface side of the substrate 81 made of Si is thermally oxidized to form a SiO₂ layer, and a ZrO₂ layer is stacked on the SiO₂ layer to form the vibration plate 82. Thereafter, an electrode material is deposited on the vibration plate 82 and patterned by etching or the like to form the first electrode 831. After a piezoelectric material is repeatedly applied and baked, patterning is performed by etching to form the piezoelectric body 832. Further, an electrode material is deposited and patterned by etching or the like to form the second electrode 833. Thereafter, the substrate 81 is etched from an opposite side of the vibration plate 82 using the SiO₂ layer as an etching stopper to form the opening 811.

In the ultrasonic element 80 according to the comparative example as described above, since the thickness of the substrate 81 is controlled by etching, surface roughness of a surface of the vibration plate 82 on the substrate 81 side increases, and it is difficult to achieve the arithmetic surface roughness of 0.4 μm±0.5 μm as in the embodiment.

Therefore, in the ultrasonic element 80 according to the comparative example, it is difficult to stably output the ultrasonic wave particularly in a low frequency band. For example, as illustrated in FIG. 9, in the ultrasonic element 80 according to the comparative example, the ultrasonic element 80 does not normally operate at about 200 kHz or less. That is, the ultrasonic element 80 according to the comparative example cannot stably output an ultrasonic wave having a frequency of 40 kHz or more up to 200 kHz.

In contrast, in the ultrasonic element 10 according to the embodiment, as indicated by the line L1, the ultrasonic wave can be stably output even in a wide frequency band of 40 kHz to 500 KHz.

### Configuration of Control Device 20

Next, the control device 20 of the super-directional speaker 1 will be described. The control device 20 includes a drive circuit unit 21 that drives the ultrasonic element 10, a memory 22 that records various information, and a processor 23 that outputs a control signal for controlling driving of the ultrasonic element 10 to the drive circuit unit 21. As described above, the super-directional speaker 1 according to the embodiment is incorporated in a small device such as a smartphone. The memory 22 and the processor 23 may be incorporated for controlling a small device, or may be incorporated independently for controlling the super-directional speaker 1.

The memory 22 records various programs and various data for controlling the super-directional speaker 1.

The processor 23 controls the super-directional speaker 1 by reading and executing a program recorded in the memory 22. Specifically, the processor 23 generates an audio signal based on, for example, an input instruction of a user, and outputs the audio signal to the drive circuit unit 21. The processor 23 generates an ultrasonic signal corresponding to the audio signal and outputs the ultrasonic signal to the drive circuit unit 21. That is, the processor 23 generates a frequency of an ultrasonic wave in synchronization with the generation of the audio signal such that a sideband component (f2±f1) generated by the nonlinear effect in the audible field 92 becomes the frequency f1 of the audio signal. That is, the processor 23 according to the embodiment functions as an audio generator and a high-frequency generator.

The drive circuit unit 21 includes a signal modulation circuit 211 as a signal modulator and an amplifier circuit 212 as an amplifier.

The audio signal and the ultrasonic signal output from the processor 23 are input to the signal modulation circuit 211 of the drive circuit unit 21, which generates a modulated signal by combining and modulating the audio signal corresponding to the audible sound and the ultrasonic signal corresponding to the ultrasonic wave.

The amplifier circuit 212 generates an amplified signal obtained by amplifying the modulated signal and inputs the amplified signal to the ultrasonic element 10.

As described above, the ultrasonic wave output from the ultrasonic element 10 is transmitted at a predetermined directional angle due to straightness of the ultrasonic wave, and the ultrasonic wave is not transmitted to a region deviated from the directional angle. In the near field 91, an ultrasonic wave having a frequency that cannot be recognized by a human auditory sense is propagated, and in the audible field 92 ahead of the near field 91, an audible sound corresponding to the audio signal is formed by the nonlinear effect of the ultrasonic wave.

### Functions and Effects of Embodiment

In the embodiment, the ultrasonic element 10 includes the substrate 11 having the vibration region 11A and the non-vibration region 11B surrounding the vibration region 11A, the first electrode 121 disposed inside the vibration region 11A, the piezoelectric body 122 disposed on the substrate 11 to cover the first electrode 121, and the second electrode 123 provided on the piezoelectric body 122. In the embodiment, the thickness of the substrate 11 along the Z direction is 2.0 μm or more and 10.0 μm or less, and more preferably 2.08 μm or more and 6.77 μm or less.

In the ultrasonic element 10 according to the embodiment, the resonance frequency is in the range from 40 kHz to 500 kHz, and the ultrasonic wave in the frequency band of 40 kHz to 500 kHz can be stably output from the ultrasonic element 10.

In the embodiment, the second electrode 123 is disposed across the vibration region 11A and the non-vibration region 11B.

The width W2 of the second electrode 123 is larger than the width W1 of the first electrode 121, and the width W0 of the vibration region 11A is larger than the width W1 of the first electrode 121 and smaller than the width W2 of the second electrode 123.

Accordingly, as described above, the ultrasonic wave in the frequency band of 40 kHz to 500 kHz can be stably output from the ultrasonic element 10.

In the embodiment, the vibration suppressor 13 is provided in a region overlapping the non-vibration region 11B when viewed from the Z direction at the first surface 113 of the substrate 1 at an opposite side of the piezoelectric body 122.

Accordingly, the vibration region 11A can be defined by the vibration suppressor 13 having a simple configuration. In this configuration, since the thickness of the substrate 11 is set to 2.0 μm or more and 10.0 μm or less by polishing the substrate 11, the thickness of the substrate 11 can be accurately controlled to a desired thickness as compared with a configuration in which the substrate 11 is etched.

In the embodiment, the arithmetic surface roughness of the first surface 113 of the substrate 11 is within a range of 0.4 μm±0.5 μm.

In such the substrate 11, as described above, the thickness of the substrate 11 can be accurately controlled to a desired thickness. It is difficult to form the first surface 113 by etching, and the first surface 113 is formed by polishing.

In the embodiment, a material for the substrate 11 is Si.

The substrate 11 made of Si has high processing accuracy, is easily formed to have a desired thickness as described above, and can stably output ultrasonic waves of 40 kHz to 500 kHz.

The super-directional speaker 1 according to the embodiment includes the ultrasonic element 10, the processor 23, the signal modulation circuit 211, and the amplifier circuit 212. The processor 23 generates an audio signal in an audible range and an ultrasonic signal in an ultrasonic band and inputs the signals to the signal modulation circuit 211. The signal modulation circuit 211 combines the audio signal and the ultrasonic signal and converts the combined signal into a modulated signal, and the amplifier circuit 212 outputs an acoustic signal obtained by amplifying the modulated signal to the ultrasonic element 10. The ultrasonic element 10 emits the input acoustic signal as acoustic vibration.

In such the super-directional speaker 1, acoustic vibration (ultrasonic wave) is emitted within a predetermined directional angle by directionality of the ultrasonic wave. The emitted acoustic vibration generates an audible sound in the audible field 92 due to the nonlinear effect of ultrasonic waves, and becomes an audible sound that can be recognized by the human auditory sense. Accordingly, it is possible to output audio in which an audible sound is audible only to the specific audible field 92.

In general, it is difficult to set the directional angle to 20 degrees or less with an ultrasonic wave having a low frequency such as 40 kHz, and thus, in the related art, a super-directional speaker using the nonlinear effect of the ultrasonic wave could only be disposed in a large space such as a museum. In contrast, in the embodiment, it is possible to output an ultrasonic wave having a frequency from 40 kHz to 500 kHz from the small ultrasonic element 10 in which the width W0 of the vibration region 11A is 2000 μm or less, and it is possible to provide the super-directional speaker 1 that can be mounted on a small device.

### Second Embodiment

Next, a second embodiment will be described.

In the first embodiment, an example is illustrated in which the shape of the vibration region 11A is defined by bonding the vibration suppressor 13 to the non-vibration region 11B.

Meanwhile, the support leg portion 141 that bonds the support substrate 14 and the substrate 11 may be bonded to the non-vibration region 11B to function as a vibration suppressor.

In the following description, the same reference signs are assigned to the already described items and the description thereof will be omitted or simplified.

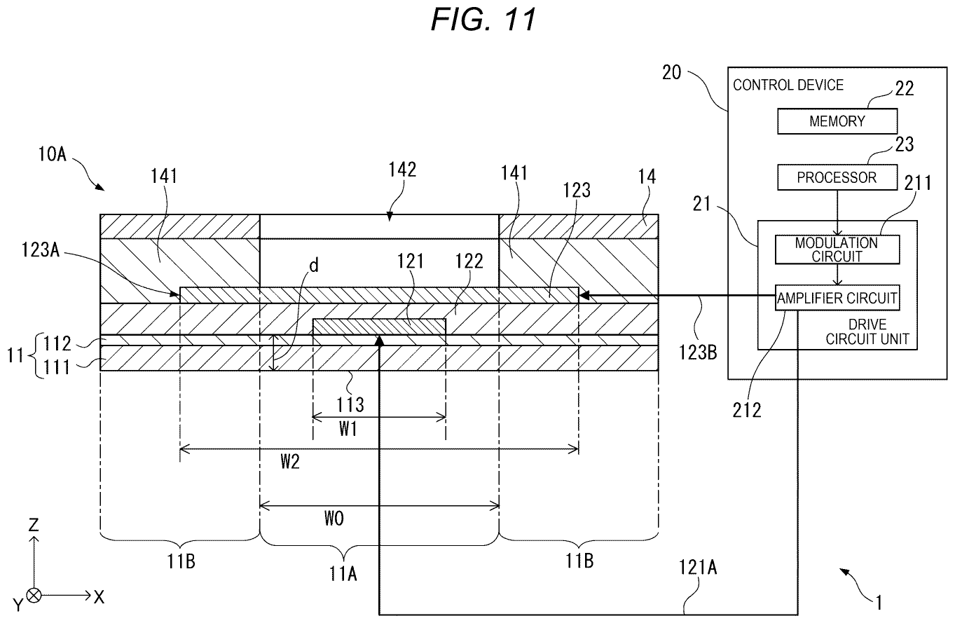

FIG. 11 is a cross-sectional view illustrating a configuration of an ultrasonic element 10A according to the second embodiment.

In the embodiment, as illustrated in FIG. 11, no vibration suppressor 13 is provided in the non-vibration region 11B at the first surface 113 of the substrate 11.

Instead, in the embodiment, the support leg portion 141 coupling the support substrate 14 and the substrate 11 is bonded to a portion of the substrate 11 corresponding to the non-vibration region 11B. Accordingly, the support leg portion 141 functions as the vibration suppressor, suppresses vibration of the non-vibration region 11B, and defines the shape of the vibration region 11A.

Similarly to the first embodiment, the support leg portion 141 according to the embodiment is bonded to cover the piezoelectric body 122 from the end edge 123A of the second electrode 123. Accordingly, it is possible to reduce burning or cracking of the piezoelectric body 122 near the end edge 123A of the second electrode 123.

In the second embodiment as well, similar operation and effect as those of the first embodiment can be achieved, and the ultrasonic wave in the frequency band of 40 kHz to 500 kHz can be stably output from the ultrasonic element 10.

### Third Embodiment

In the first embodiment, the super-directional speaker 1 including the ultrasonic element 10 is exemplified, but the present disclosure is not limited thereto.

In a third embodiment, an information device that transmits a signal by ultrasonic waves will be described as a small device including the ultrasonic element 10.

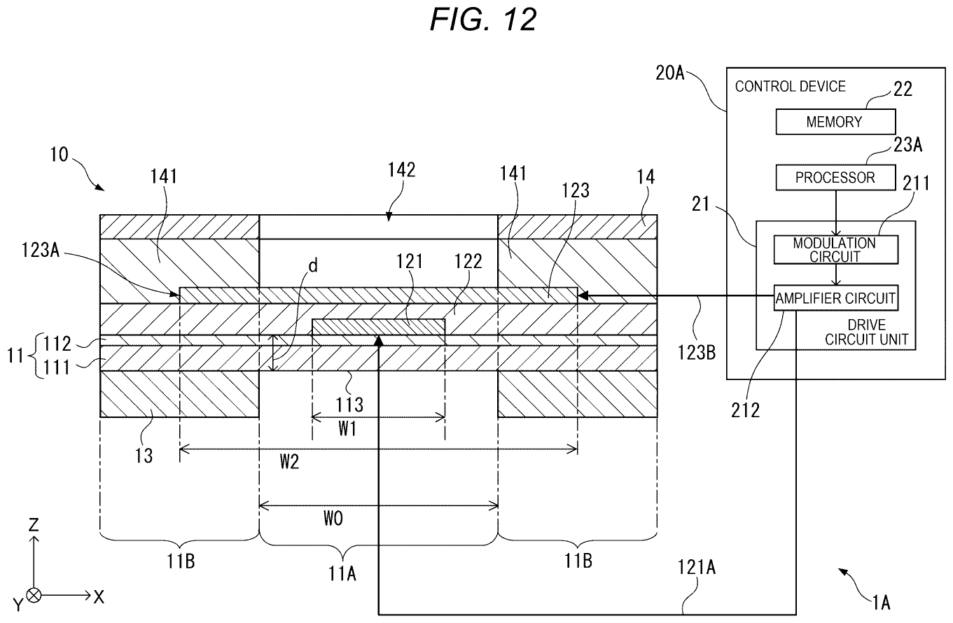

FIG. 12 is a diagram illustrating a schematic configuration of an information device 1A according to the third embodiment.

As illustrated in FIG. 12, the information device 1A according to the embodiment includes the ultrasonic element 10 and a control device 20A.

A configuration of the ultrasonic element 10 is the similar as that of the first embodiment described above, and the description thereof will be omitted here. As in the second embodiment, the ultrasonic element 10 may have a configuration in which the vibration region 11A is defined by the support leg portion 141 instead of the vibration suppressor 13.

Similarly to the first embodiment, the control device 20A of the information device 1A according to the embodiment includes the drive circuit unit 21 that drives the ultrasonic element 10, the memory 22 that records various information, and a processor 23A that outputs a control signal for controlling driving of the ultrasonic element 10 to the drive circuit unit 21.

In the embodiment, the processor 23A functions as a baseband signal generator and a carrier signal generator in the present disclosure by reading and executing a program recorded in the memory 22.

That is, the processor 23A generates a baseband signal based on, for example, an input instruction of a user. The baseband signal is a signal including various content data, and the content data can be various data such as text data, audio data, and image data. The processor 23A encrypts the content data into audio data using an algorithm such as Advanced Encryption Standard (AES) or Rivest-Shamir-Adleman (RSA).

The processor 23A generates a carrier signal corresponding to the generated baseband signal. The carrier signal is an ultrasonic signal, and an ultrasonic frequency is generated based on a frequency of the baseband signal which is audio data. This ultrasonic wave can be set in a frequency band of 40 kHz to 500 kHz as in the first embodiment.

The processor 23A outputs the baseband signal and the carrier signal to the signal modulation circuit 211 of the drive circuit unit 21.

Accordingly, as in the first embodiment, the signal modulation circuit 211 generates a modulated signal obtained by combining the baseband signal and the carrier signal, and outputs the generated modulated signal to the amplifier circuit 212.

The amplifier circuit 212 amplifies the modulated signal into an acoustic signal and outputs the acoustic signal to the ultrasonic element 10.

Accordingly, in the ultrasonic element 10, the vibration region 11A vibrates by the input acoustic signal to output acoustic vibration.

When such the information device 1A is used, as in the first embodiment, highly directional information communication is possible, information by ultrasonic waves can be propagated within a range of a predetermined directional angle, information is not received in the near field 91, but can be received in the audible field 92.

That is, the baseband signal appears in the audible field 92 due to the nonlinear effect of the ultrasonic wave, and the baseband signal output from the information device 1A can be received by holding a receiver (not illustrated) over the audible field 92.

Since such the information device 1A can receive information only in an output direction of the ultrasonic wave output from the ultrasonic element 10 and in the audible field 92 at a predetermined distance set in advance from the ultrasonic element 10, it is possible to transmit and receive highly confidential information.

### Modifications

The present disclosure is not limited to the embodiments and modifications described above. The present disclosure includes modifications, improvements, and configurations obtained by appropriately combining the embodiments within a scope where an object of the present disclosure can be achieved.

In the above embodiments, the super-directional speaker 1 and the information device 1A including the ultrasonic element 10 (or the ultrasonic element 10A according to the second embodiment) are exemplified, but the ultrasonic element 10 according to the present disclosure (or the ultrasonic element 10A according to the second embodiment) can be applied to any other devices.

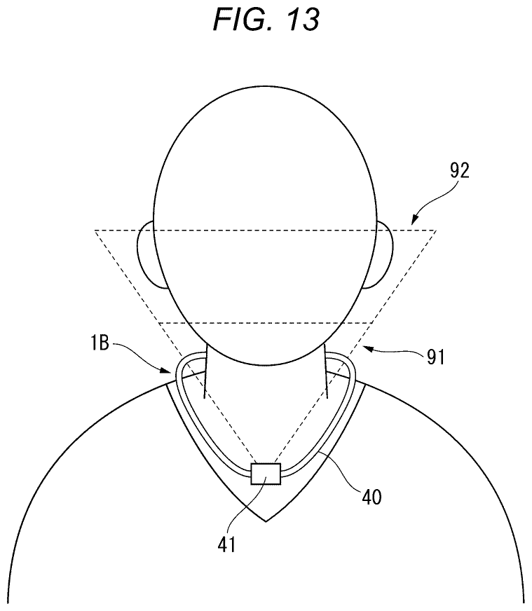

FIGS. 13 to 15 are diagrams illustrating other application examples of the ultrasonic element 10.

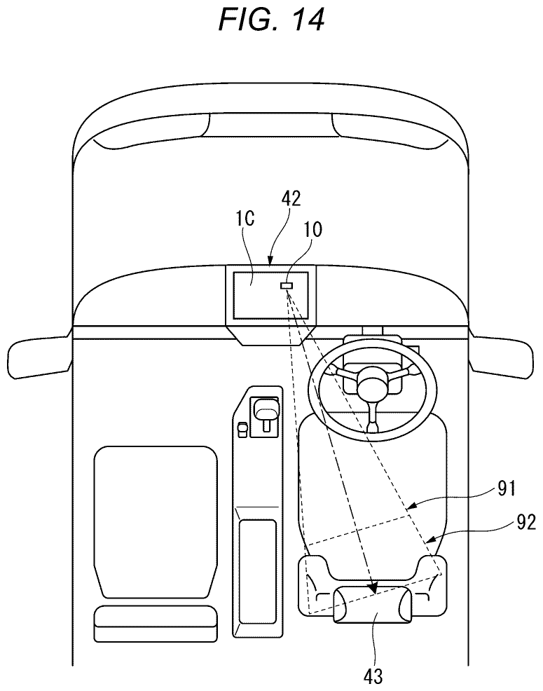

For example, the super-directional speaker 1 can be applied to a wireless speaker as illustrated in FIG. 11, a car navigation device as illustrated in FIG. 12, and an indoor content output device as illustrated in FIG. 13, in addition to small devices such as a smartphone, a tablet terminal, and a notebook personal computer described in the first embodiment. The information device 1A can be applied to an operation panel or the like as illustrated in FIG. 14.

A wireless speaker 1B illustrated in FIG. 13 is a speaker for wearing around a neck, and has a speaker portion 41 provided on a neckband 40 worn around the neck.

The speaker portion 41 is provided with the ultrasonic element 10 used in the first embodiment or the ultrasonic element 10A according to the second embodiment, and the drive circuit unit 21. The drive circuit unit 21 can communicate with a mobile terminal device such as a smartphone, receives an audio signal and an ultrasonic signal from the mobile terminal device, generates a modulated signal obtained by combining these signals, amplifies the modulated signal to generate an acoustic signal, and outputs the acoustic signal to the ultrasonic element 10. Accordingly, similarly to the super-directional speaker 1 according to the first embodiment, a sound is only audible in the predetermined audible field 92 (in this example, near an ear of a head).

A navigation device 1C illustrated in FIG. 14 is a device that is fixed to a center panel 42 of a vehicle and guides a driver of the vehicle along a travel route of the vehicle.

The ultrasonic element 10 used in the first embodiment (or the ultrasonic element 10A according to the second embodiment) is incorporated in the navigation device 1C, and a transmission direction of the ultrasonic wave of the ultrasonic element 10 is directed toward a driver's seat 43 of the vehicle. The audible field 92 of the ultrasonic element 10 in the navigation device 1C is formed near a head of the driver seated in the driver's seat 43.

In such a configuration, the travel route from the navigation device 1C can be guided only to the driver in the vehicle by a sound. A passenger sitting in a passenger seat or a rear seat does not hear audio guidance of the travel route. A passenger seated in a passenger seat or a rear seat can hear only audio content such as music output from, for example, an in-vehicle speaker, and the audio guidance of the travel route is not mixed in the content, so that the passenger can comfortably enjoy the content.

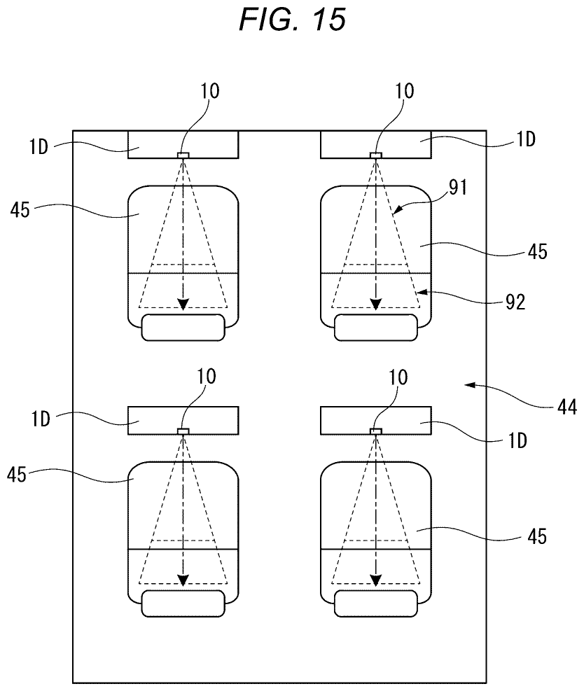

A plurality of indoor content output devices 1D illustrated in FIG. 15 are provided in one interior 44. Examples of the interior include an interior of an automobile. In the interior 44, seats 45 are provided corresponding to the respective indoor content output devices 1D. Each indoor content output device 1D has the ultrasonic element 10 used in the first embodiment (or the ultrasonic element 10A according to the second embodiment) built in, and a transmission direction of the ultrasonic wave of the ultrasonic element 10 is directed to a direction toward the seat 45 corresponding to the indoor content output device 1D.

Accordingly, a user can hear only a sound output from the indoor content output device 1D corresponding to the seat 45 on which the user is seated, and cannot hear a sound output from the indoor content output device 1D corresponding to another seat. Therefore, for example, when a plurality of users are seated in a closed space such as a vehicle interior, it is possible to select content that each user wants to view individually.

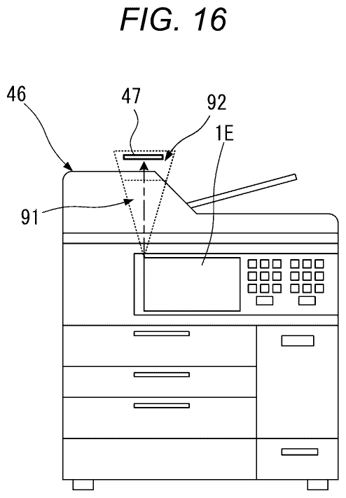

An operation panel 1E illustrated in FIG. 16 can be applied to, for example, a copy machine 46 installed in a store such as a convenience store.

A user may print image data stored in a mobile terminal device such as a smartphone with the copy machine 46 installed in a store. In such a case, it is necessary to specify the copy machine 46 that performs printing.

In the copy machine 46 illustrated in FIG. 16, the information device 1A as illustrated in the third embodiment is built in the operation panel 1E, and information can be received by a receiver (for example, a mobile terminal device 47 such as a smartphone owned by a user) provided in the predetermined audible field 92. For example, information for identifying the copy machine 46 is in a baseband signal, and a modulated signal obtained by combining the baseband signal and a carrier signal is output from the ultrasonic element 10. Accordingly, the baseband signal can be received only in the audible field 92 formed at a predetermined distance E from the operation panel 1E, and the mobile terminal device 47 can specify the copy machine 46 by holding the mobile terminal device 47 over the audible field 92.

### Summary of Present Disclosure

An ultrasonic element according to a first aspect of the present disclosure includes: a substrate having a vibration region and a non-vibration region surrounding the vibration region; a first electrode disposed inside the vibration region; a piezoelectric body disposed on the substrate to cover the first electrode; and a second electrode provided on the piezoelectric body, in which a direction in which the substrate, the first electrode, the piezoelectric body, and the second electrode are stacked is a stacking direction, and a thickness of the substrate along the stacking direction is 2.0 μm or more and 10.0 μm or less.

Accordingly, an ultrasonic element having a resonance frequency of 40 kHz to 500 kHz can be implemented, and an ultrasonic wave in a frequency band of 40 kHz to 500 kHz can be stably output from the ultrasonic element.

In the ultrasonic element according to the aspect, the second electrode is disposed across the vibration region and the non-vibration region.

Accordingly, compared with a case where the second electrode is provided only in the vibration region, the resonance frequency of the ultrasonic element can be reduced, and the ultrasonic wave in the frequency band of 40 kHz to 500 kHz can be stably output from the ultrasonic element.

In the ultrasonic element according to the aspect, when viewed from the stacking direction, a width of the second electrode is larger than a width of the first electrode, and a width of the vibration region is larger than the width of the first electrode and smaller than the width of the second electrode.

Accordingly, compared with a case where the width of the vibration region is larger than the width of the second electrode and the first electrode and the second electrode are accommodated in the vibration region, the resonance frequency of the ultrasonic element can be reduced, and the ultrasonic wave in the frequency band of 40 kHz to 500 kHz can be stably output from the ultrasonic element.

The ultrasonic element according to the aspect includes a vibration suppressor disposed in a region overlapping the non-vibration region when viewed from the stacking direction at a surface of the substrate at an opposite side of the piezoelectric body.

Accordingly, it is possible to suppress vibration of the non-vibration region outside the vibration region.

The ultrasonic element according to the aspect may include: a support substrate facing a surface of the piezoelectric body at an opposite side of the substrate and a surface of the second electrode at the opposite side of the substrate; and a vibration suppressor disposed in a region overlapping the non-vibration region when viewed from the stacking direction, between the piezoelectric body and the second electrode, and the support substrate.

Even in such a configuration, it is possible to suppress vibration of the non-vibration region outside the vibration region.

When using the vibration suppressor that bonds the substrate and the support substrate as described above, the vibration suppressor preferably covers the piezoelectric body from an end edge of the second electrode.

Accordingly, it is possible to reduce problems such as cracking or burning occurring between the end edge of the second electrode and the piezoelectric body.

In the ultrasonic element according to the aspect, an arithmetic surface roughness of a surface of the substrate at an opposite side of the piezoelectric body is within a range of 0.4 μm±0.5 μm.

Accordingly, a thickness of the substrate becomes uniform, and the ultrasonic wave of 40 kHz to 500 kHz can be stably output.

In the ultrasonic element according to the aspect, a material for the substrate is Si.

By using the substrate made of Si, processing accuracy of the substrate can be improved. Therefore, a substrate having the arithmetic surface roughness of 0.4 μm±0.5 μm and a thickness of 2.0 μm to 10.0 μm described above can be obtained.

An information device according to a second aspect of the present disclosure includes: the ultrasonic element according to the first aspect; a baseband signal generator configured to generate a baseband signal; carrier signal generator configured to generate a carrier signal in an ultrasonic band; a signal modulator configured to combine the baseband signal and the carrier signal and convert the combined signal into a modulated signal; and an amplifier configured to amplify the modulated signal and output an acoustic signal, in which the ultrasonic element emits the input acoustic signal as acoustic vibration.

In the ultrasonic element as described above, when the acoustic signal as described above is input, acoustic vibration is emitted. The acoustic vibration is propagated to a near field and an audible field farther from the ultrasonic element than the near field. Since the ultrasonic wave is linearly propagated in the near field, the baseband signal does not appear. Meanwhile, in the audible field, the carrier signal and the baseband signal are separated by the nonlinear effect of the ultrasonic wave, and information in the baseband signal can be received by another device such as a receiver.

In the information device according to the aspect, a frequency of the carrier signal is 40 kHz or more and 500 kHz or less.

By using such a carrier signal, straightness of the acoustic vibration is increased, and the acoustic vibration can be propagated only within a predetermined directional angle.

A super-directional speaker according to a third aspect of the present disclosure includes: the ultrasonic element according to the first aspect; an audio generator configured to generate an audio signal in an audible range; a high-frequency generator configured to generate an ultrasonic signal in an ultrasonic band; a signal modulator configured to combine the audio signal and the ultrasonic signal and convert the combined signal into a modulated signal; and an amplifier configured to amplify the modulated signal and output an acoustic signal, in which the ultrasonic element emits the input acoustic signal as acoustic vibration.

Similarly to the second aspect, when the acoustic signal is input, the ultrasonic element emits the acoustic vibration that propagates to the near field and the audible field. Accordingly, it is possible to output an audible sound that is audible only in the audible field.

In the super-directional speaker according to the aspect, a frequency of the ultrasonic signal is 40 kHz or more and 500 kHz or less.

By using such an ultrasonic wave, straightness of the acoustic vibration is increased, and the acoustic vibration can be propagated only within a predetermined directional angle.

What is claimed is:

1. An ultrasonic element comprising:
a substrate having a vibration region and a non-vibration region surrounding the vibration region;
a first electrode disposed inside the vibration region;
a piezoelectric body disposed on the substrate to cover the first electrode; and
a second electrode provided on the piezoelectric body, wherein
a direction in which the substrate, the first electrode, the piezoelectric body, and the second electrode are stacked is a stacking direction, and a thickness of the substrate along the stacking direction is 2.0 μm or more and 10.0 μm or less.

2. The ultrasonic element according to claim 1, wherein
the second electrode is disposed across the vibration region and the non-vibration region.

3. The ultrasonic element according to claim 2, wherein
when viewed from the stacking direction, a width of the second electrode is larger than a width of the first electrode, and a width of the vibration region is larger than the width of the first electrode and smaller than the width of the second electrode.

4. The ultrasonic element according to claim 1, comprising:
a vibration suppressor disposed in a region overlapping the non-vibration region when viewed from the stacking direction at a surface of the substrate at an opposite side of the piezoelectric body.

5. The ultrasonic element according to claim 1, comprising:
a support substrate facing a surface of the piezoelectric body at an opposite side of the substrate and a surface of the second electrode at the opposite side of the substrate; and
a vibration suppressor disposed region overlapping the non-vibration region when viewed from the stacking direction, between the piezoelectric body and the second electrode, and the support substrate.

6. The ultrasonic element according to claim 5, wherein
the vibration suppressor covers the piezoelectric body from an end edge of the second electrode.

7. The ultrasonic element according to claim 1, wherein
an arithmetic surface roughness of a surface of the substrate at an opposite side of the piezoelectric body is within a range of 0.4 μm±0.5 μm.

8. The ultrasonic element according to claim 1, wherein
a material for the substrate is Si.

9. An information device comprising:
the ultrasonic element according to claim 1;
a baseband signal generator configured to generate a baseband signal;
a carrier signal generator configured to generate a carrier signal in an ultrasonic band;
a signal modulator configured to combine the baseband signal and the carrier signal and convert the combined signal into a modulated signal; and
an amplifier configured to amplify the modulated signal and output an acoustic signal, wherein
the ultrasonic element emits the input acoustic signal as acoustic vibration.

10. The information device according to claim 9, wherein
a frequency of the carrier signal is 40 kHz or more and 500 kHz or less.

11. A super-directional speaker comprising:
the ultrasonic element according to claim 1;
an audio generator configured to generate an audio signal in an audible range;
a high-frequency generator configured to generate an ultrasonic signal in an ultrasonic band;
a signal modulator configured to combine the audio signal and the ultrasonic signal and convert the combined signal into a modulated signal; and
an amplifier configured to amplify the modulated signal and output an acoustic signal, wherein
the ultrasonic element emits the input acoustic signal as acoustic vibration.

12. The super-directional speaker according to claim 11, wherein
a frequency of the ultrasonic signal is 40 kHz or more and 500 kHz or less.
